(19) United States
(12) Patent Application Publication
(10) Pub. No.: US 2026/0018562 A1
(43) Pub. Date: Jan. 15, 2026

(54) SEMICONDUCTOR DEVICE

(71) Applicant: Rohm Co., Ltd., Kyoto-shi (JP)

(72) Inventor: Tomohira KIKUCHI, Kyoto-shi (JP)

(21) Appl. No.: 19/331,726

(22) Filed: Sep. 17, 2025

Related U.S. Application Data
(63) Continuation of application No. PCT/JP2024/007994, filed on Mar. 4, 2024.

(30) Foreign Application Priority Data
Mar. 24, 2023 (JP) 2023-048263

(51) Int. Cl. H01L 25/065; H01L 23/00; H01L 23/495; H01L 23/544

(52) U.S. Cl. CPC H01L 25/0655; H01L 23/49513; H01L 23/49555; H01L 23/49575; H01L 23/544; H01L 24/32; H01L 24/48; H01L 24/73; H01L 2224/32245; H01L 2224/4814; H01L 2224/48245; H01L 2224/73265

(57) ABSTRACT

A semiconductor device includes a first die pad, a first semiconductor element, a second die pad, a second semiconductor element, a sealing resin, a first lead, a second lead, a third lead, and a fourth lead. The first lead, the second lead, the third lead, and the fourth lead are each spaced apart from the third side and the fourth side of the sealing resin and are exposed externally from either the first side surface or the second side surface of the sealing resin. Viewed in a third direction perpendicular to the first direction and the second directions, an area of the first die pad is larger than an area of the second die pad. Viewed in the third direction, each of the first lead and the third lead is separated away in the first direction from a first virtual line toward a side where the first side surface of the sealing resin is located.

### TECHNICAL FIELD

The present disclosure relates to a semiconductor device.

### BACKGROUND ART

The semiconductor device disclosed in JP-A-2016-207714 comprises two die pads, a control element (controller) and a drive element (gate driver) individually mounted on the two die pads, and a sealing resin covering the two die pads, the control element, and the drive element. This semiconductor device drives switching elements such as IGBTs and MOSFETs. This semiconductor device is used in inverter circuits, and so forth.

In this semiconductor device, the power supply voltage supplied to the drive element is at least equal to the voltage applied to the switching element. Therefore, the power supply voltage supplied to the control element differs from the power supply voltage supplied to the drive element. Consequently, a difference arises between the voltage applied to the control element and its conductive path and the voltage applied to the drive element and its conductive path. Therefore, in the semiconductor device, an insulating element is interposed in the electrical signal transmission path between the control element and the drive element, thereby insulating the control element and its conductive path from the drive element and its conductive path. This prevents electrical breakdown in each of the control element and the drive element.

In this semiconductor device, the two die pads include a first die pad mounted with the control element and the insulating element, and a second die pad mounted with the drive element. The semiconductor device further includes a first lead connected to one side of the first die pad in a first direction (the X-direction shown in JP-A-2016-207714) and a second lead facing the first lead in a second direction (the Y-direction shown in JP-A-2016-207714). The second lead is positioned closer to the second die pad than the first lead is. Viewed in the thickness direction of the semiconductor device, the area of the first die pad is larger than the area of the second die pad. In this case, the dimension in the second direction of the portion of the first lead covered by the sealing resin may become excessively larger than the dimension in the second direction of the portion of the second lead covered by the sealing resin. Consequently, during the formation of the sealing resin, molten resin tends to flow more readily toward the second die pad than toward the first die pad, potentially resulting in insufficient filling of the sealing resin. Insufficient filling of the sealing resin increases the proportion of voids within the sealing resin, raising concerns about a reduction in the insulation withstand voltage of the semiconductor device.

### BRIEF DESCRIPTION OF THE DRAWINGS

FIG. 1 is a plan view of a semiconductor device according to a first embodiment of the present disclosure.

FIG. 2 is a plan view corresponding to FIG. 1, showing the sealing resin in a transparent state.

FIG. 3 is a plan view corresponding to FIG. 2, showing each of a first semiconductor element, a second semiconductor element, and an insulating element as being transparent, while omitting the depiction of plurality of first wires to plurality of fourth wires.

FIG. 4 is a rear view of the semiconductor device shown in FIG. 1.

FIG. 5 is a front view of the semiconductor device shown in FIG. 1.

FIG. 6 is a left side view of the semiconductor device shown in FIG. 1.

FIG. 7 is a right side view of the semiconductor device shown in FIG. 1.

FIG. 8 is a cross-sectional view along line VII-VIII in FIG. 2.

FIG. 9 is a cross-sectional view along line IX-IX in FIG. 2.

FIG. 10 is a cross-sectional view along line X-X in FIG. 2.

FIG. 11 is a plan view of the semiconductor device according to a second embodiment of the present disclosure.

FIG. 12 is a plan view corresponding to FIG. 11, showing the sealing resin as being transparent.

FIG. 13 is a plan view corresponding to FIG. 12, showing each of the first semiconductor element, the second semiconductor element, and the insulating element as being transparent, while omitting the depiction of the plurality of first wires to the plurality of fourth wires.

FIG. 14 is a rear view of the semiconductor device shown in FIG. 11.

FIG. 15 is a front view of the semiconductor device shown in FIG. 11.

FIG. 16 is a cross-sectional view along line XVI-XVI in FIG. 12.

FIG. 17 is a cross-sectional view along line XVII-XVII in FIG. 12.

FIG. 18 is a plan view of the semiconductor device according to a third embodiment of the present disclosure.

FIG. 19 is a rear view of the semiconductor device shown in FIG. 18.

FIG. 20 is a front view of the semiconductor device shown in FIG. 18.

FIG. 21 is a plan view of the semiconductor device according to a fourth embodiment of the present disclosure.

FIG. 22 is a rear view of the semiconductor device shown in FIG. 21.

FIG. 23 is a front view of the semiconductor device shown in FIG. 21.

### DETAILED DESCRIPTION OF EMBODIMENTS

The following describes preferred embodiments of the present disclosure with reference to the accompanying drawings.

### First Embodiment

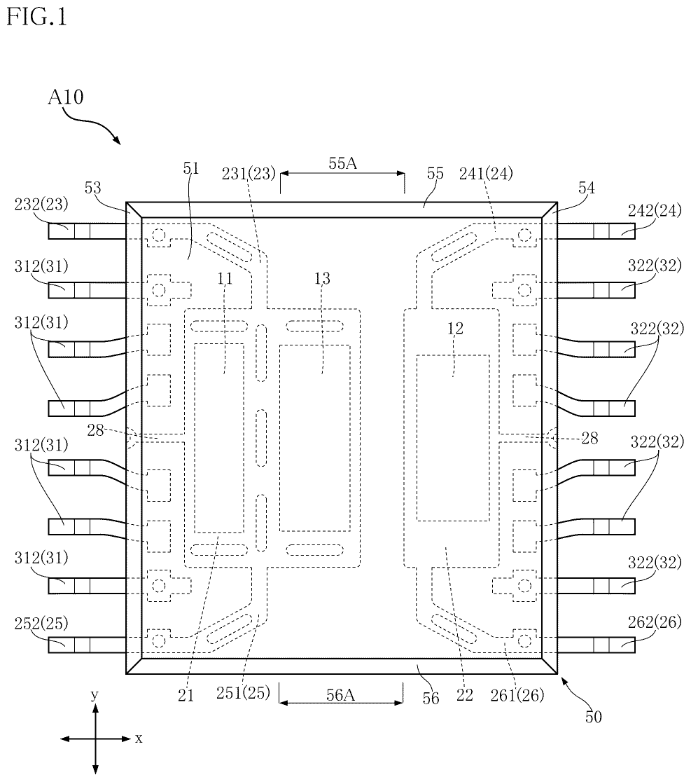

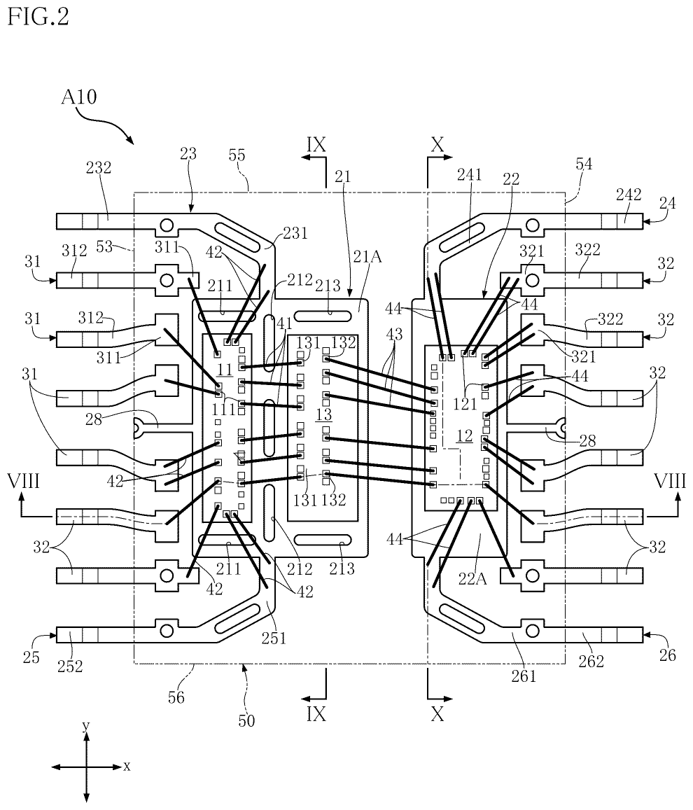

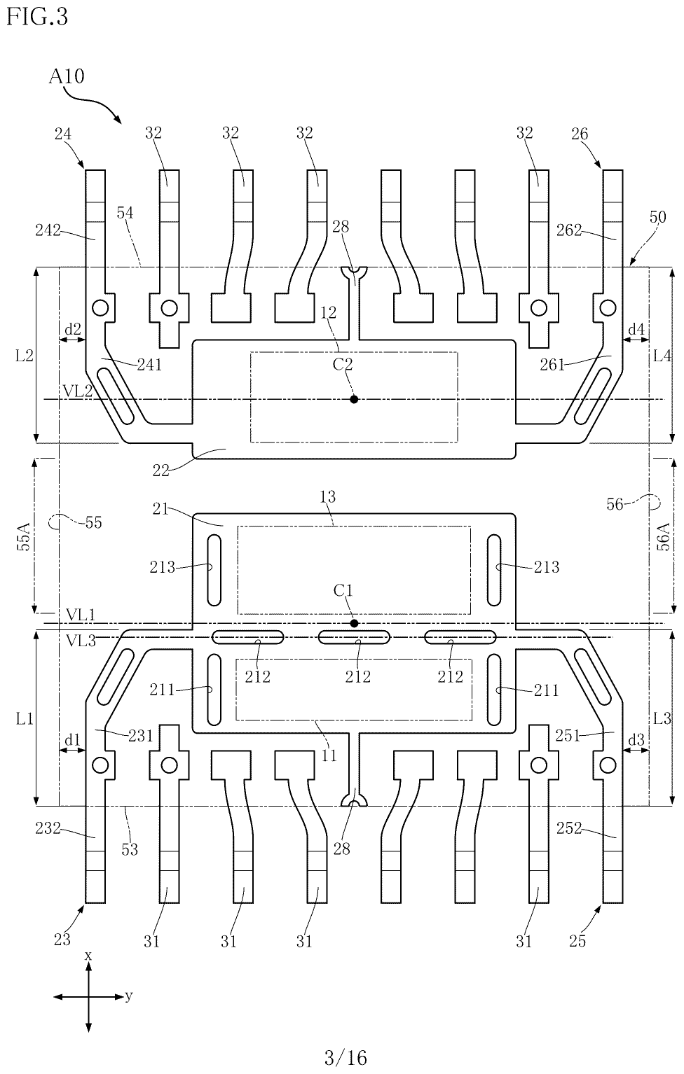

Based on FIGS. 1 to 10, the semiconductor device A10 according to a first embodiment of the present disclosure will be described. The semiconductor device A10 includes a first semiconductor element 11, a second semiconductor element 12, an insulating element 13, a first die pad 21, a second die pad 22, a first lead 23, a second lead 24, a third lead 25, a fourth lead 26, a plurality of first intermediate leads 31, a plurality of second intermediate leads 32, and a sealing resin 50. Furthermore, the semiconductor device A10 includes two support leads 28, a plurality of first wires 41, a plurality of second wires 42, a plurality of third wires 43, and a plurality of fourth wires 44. Semiconductor device A10 is surface-mounted onto a wiring board of an inverter device, such as an electric vehicle or a hybrid vehicle. The package form of the semiconductor device A10 is a Small Outline Package (SOP). However, the package form of the semiconductor device A10 is not limited to SOP. Here, FIG. 2 is shown through the sealing resin 50 for ease of understanding. In FIG. 2, the outline of the sealing resin 50 is indicated by an imaginary line (two-dot dashed line). For ease of understanding, as differences from FIG. 2, FIG. 3 shows the first semiconductor element 11, the second semiconductor element 12, and the insulating element 13 as being transparent, and omits the depiction of each of the plurality of first wires 41 to the plurality of fourth wires 44. In FIG. 3, the outer contours of the first semiconductor element 11, the second semiconductor element 12, the insulating element 13, and the sealing resin 50 are each indicated by imaginary lines.

For the sake of convenience in describing the semiconductor device A10, one example of a direction perpendicular to the normal direction of the first mounting surface 21A of the first die pad 21 described later is referred to as a “first direction x”. One example of a direction perpendicular to the first direction x is referred to as a “second direction y”. The second direction y is perpendicular to the normal direction of the first mounting surface 21A. A direction perpendicular to both the first direction x and the second direction y is referred to as a “third direction z”. The third direction z corresponds to the normal direction of the first mounting surface 21A.

In the semiconductor device A10, the first semiconductor element 11, the second semiconductor element 12, and the insulating element 13 are each formed as individual elements. The second semiconductor element 12 is positioned on the opposite side from the first semiconductor element 11 relative to the insulating element 13 in the first direction x. The insulating element 13 is positioned adjacent to the first semiconductor element 11 in the second direction y. Viewed in the third direction z, the first semiconductor element 11, the second semiconductor element 12, and the insulating element 13 are each rectangular with the second direction y as their long side.

The first semiconductor element 11 controls the second semiconductor element 12. The first semiconductor element 11 includes a circuit for converting electrical signals input from other semiconductor devices into PWM control signals, a transmission circuit for transmitting said PWM control signals to the second semiconductor element 12, and a reception circuit for receiving electrical signals from the second semiconductor element 12.

The second semiconductor element 12 drives a switching element located outside the semiconductor device A10. The switching element is, for example, an IGBT (Insulated Gate Bipolar Transistor) or a MOSFET (Metal-Oxide-Semiconductor Field-Effect Transistor). The second semiconductor element 12 includes a receiving circuit for receiving PWM control signals, a circuit for driving the switching element based on said PWM control signals, and a transmitting circuit for transmitting electrical signals to the first semiconductor element 11. Said electrical signals may be, for example, output signals from a temperature sensor positioned near the motor.

The insulating element 13 transmits electrical signals, such as PWM (Pulse Width Modulation) control signals, in an insulated state. The insulating element 13 is of the inductively coupled type. An insulating transformer is one example of an inductively coupled insulating element 13. The isolation transformer transmits electrical signals in an insulated state by inductively coupling two inductors (coils). These two inductors include a transmitter-side inductor and a receiver-side inductor. Each of these two inductors is stacked in the third direction z. A dielectric layer, constituted by materials such as silicon dioxide (SiO₂), is located between the transmitter-side inductor and the receiver-side inductor. This dielectric layer electrically insulates the transmitter-side inductor from the receiver-side inductor. Alternatively, the insulating element 13 may be capacitive. An example of a capacitive type insulating element 13 is a capacitor.

The voltage applied to the first semiconductor element 11 and the second semiconductor element 12 is different for each. Therefore, an electric potential difference occurs between the first semiconductor element 11 and the second semiconductor element 12. In the semiconductor device A10, the voltage applied to the second semiconductor element 12 is higher than the voltage applied to the first semiconductor element 11. Furthermore, in the semiconductor device A10, the power supply voltage supplied to the second semiconductor element 12 is higher than the power supply voltage supplied to the first semiconductor element 11.

Therefore, in the semiconductor device A10, a first circuit including the first semiconductor element 11 and a second circuit including the second semiconductor element 12 are mutually insulated from each other by the insulating element 13. The insulating element 13 is conductive to the first circuit and the second circuit. The first circuit includes, in addition to the first semiconductor element 11, the first lead 23, the third lead 25, and the plurality of first intermediate leads 31. The second circuit includes, in addition to the second die pad 22, the second lead 24, the fourth lead 26, and the plurality of second intermediate leads 32. The first circuit and the second circuit have relatively different electric potentials. In the semiconductor device A10, the electric potential of the first circuit is higher than that of the second circuit. Furthermore, the insulating element 13 relays mutual signals between the first circuit and the second circuit. For example, in the inverter device of an electric vehicle or hybrid vehicle, while the voltage applied to the ground (GND) of the first semiconductor element 11 is approximately 0V, the voltage applied to the ground of the second semiconductor element 12 can transiently exceed 600V.

As shown in FIGS. 2 and 8, the first semiconductor element 11 has a plurality of first electrodes 111. The plurality of first electrodes 111 are provided on the upper surface of the first semiconductor element 11 (the surface facing the same side as the first mounting surface 21A of the first die pad 21 described later). The plurality of first electrodes 111 include, for example, aluminum (Al). The plurality of first electrodes 111 are conducted to the circuit formed in the first semiconductor element 11.

As shown in FIGS. 2 and 8, the second semiconductor element 12 has a plurality of second electrodes 121. The plurality of second electrodes 121 are provided on the upper surface of the second semiconductor element 12 (the surface facing the same side as the second mounting surface 22A of the second die pad 22 described later). The plurality of second electrodes 121 contain, for example, aluminum. The plurality of second electrodes 121 are conducted to the circuit formed in the second semiconductor element 12.

As shown in FIGS. 2 and 8, the insulating element 13 is located between the second semiconductor element 12 and the first semiconductor element 11 in the third direction z. Therefore, the first semiconductor element 11 is positioned on the opposite side from the second semiconductor element 12 relative to the insulating element 13 in the first direction x. The upper surface of the insulating element 13 (the surface facing the same side as the first mounting surface 21A of the first die pad 21 described later) is provided with a plurality of third electrodes 131 and a plurality of fourth electrodes 132. Each of the plurality of third electrodes 131 and the plurality of fourth electrodes 132 is conducted to either the transmit-side inductor or the receive-side inductor. The plurality of third electrodes 131 are arranged along the second direction y and are located between the first semiconductor element 11 and the second semiconductor element 12 in the first direction x. The plurality of fourth electrodes 132 are arranged along the second direction y and are positioned on the opposite side from the first semiconductor element 11 in the first direction x, relative to the plurality of third electrodes 131. The plurality of third electrodes 131 and the plurality of fourth electrodes 132 contain, for example, aluminum.

The sealing resin 50 covers the first semiconductor element 11, the second semiconductor element 12, the insulating element 13, the first die pad 21, and the second die pad 22, as shown in FIG. 1. As shown in FIG. 8, the sealing resin 50 further covers the plurality of first wires 41, the plurality of second wires 42, the plurality of third wires 43, and the plurality of fourth wires 44. The sealing resin 50 is an insulator. The sealing resin 50 is made of a material including, for example, epoxy resin. Viewed in the third direction z, the sealing resin 50 is rectangular.

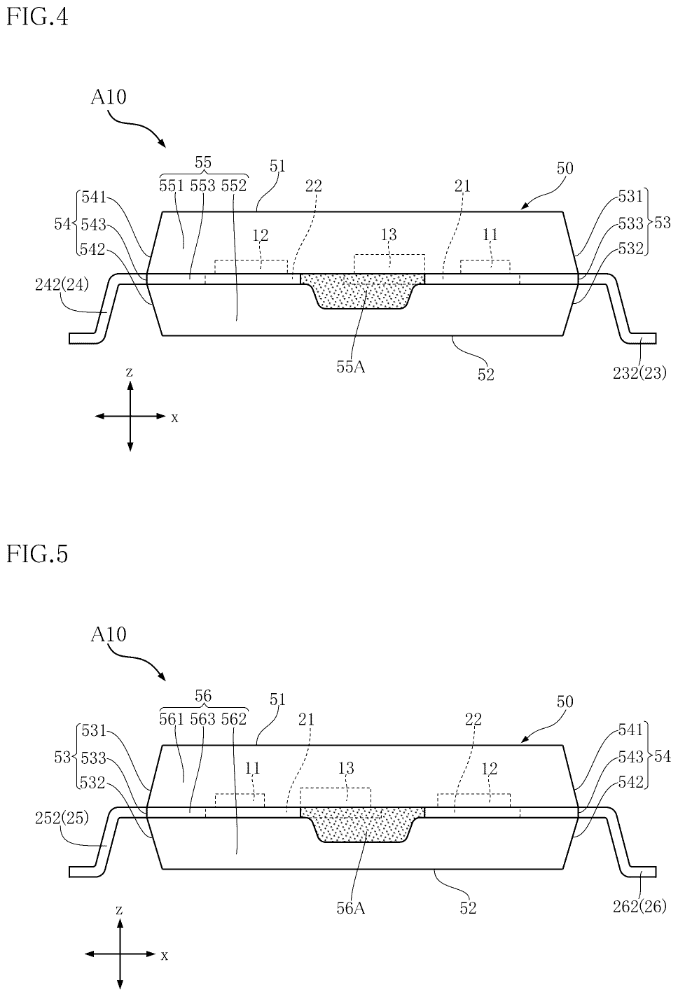

As shown in FIGS. 4 to 7, the sealing resin 50 has a top surface 51, a bottom surface 52, a first side surface 53, a second side surface 54, a third side surface 55, and a fourth side surface 56.

As shown in FIGS. 4 to 7, the top surface 51 and the bottom surface 52 face away from each other in the third direction z. The top surface 51 and bottom surface 52 are each substantially flat.

As shown in FIGS. 4 to 6, the first side surface 53 connects to the top surface 51 and bottom surface 52 and faces one side in the first direction x. The first side surface 53 is positioned closer to the first die pad 21 than the second side surface 54 is. The first side surface 53 includes a first upper portion 531, a first lower portion 532, and a first intermediate portion 533. The first upper portion 531 connects to the top surface 51 on one side in the third direction z and connects to the first intermediate portion 533 on the other side in the third direction z. The first upper portion 531 is inclined relative to the top surface 51. The first lower portion 532 connects to the bottom surface 52 on one side in the third direction z and connects to the first intermediate portion 533 on the other side in the third direction z. The first lower portion 532 is inclined relative to the bottom surface 52. The first intermediate portion 533 is located between the first upper portion 531 and the first lower portion 532 in the third direction z. The in-plane direction of the first intermediate portion 533 includes the third direction z. Viewed in the third direction z, the first intermediate portion 533 is positioned outwardly relative to the top surface 51 and the bottom surface 52.

As shown in FIGS. 4, 5, and 7, the second side surface 54 connects to the top surface 51 and the bottom surface 52 and faces away from the first side surface 53 in the first direction x. The second side surface 54 is positioned closer to the second die pad 22 than the first side surface 53 is. The second side surface 54 includes a second upper portion 541, a second lower portion 542, and a second intermediate portion 543. The second upper portion 541 connects to the top surface 51 on one side in the third direction z and connects to the second intermediate portion 543 on the other side in the third direction z. The second upper portion 541 is inclined relative to the top surface 51. The second lower portion 542 connects to the bottom surface 52 on one side in the third direction z and connects to the second intermediate portion 543 on the other side in the third direction z. The second lower portion 542 is inclined relative to the bottom surface 52.

The second intermediate portion 543 is located between the second upper portion 541 and the second lower portion 542 in the third direction z. The in-plane direction of the second intermediate portion 543 includes the third direction z. Viewed in the third direction z, the second intermediate portion 543 is positioned outwardly relative to the top surface 51 and the bottom surface 52.

As shown in FIGS. 4, 6, and 7, the third side surface 55 connects to the top surface 51 and the bottom surface 52 and faces one side in the second direction y. The third side surface 55 includes a third upper portion 551, a third lower portion 552, and a third intermediate portion 553. The third upper portion 551 connects to the top surface 51 on one side in the third direction z and connects to the third intermediate portion 553 on the other side in the third direction z. The third upper portion 551 is inclined relative to the top surface 51. The third lower portion 552 connects to the bottom surface 52 on one side of the third direction z and connects to the third intermediate portion 553 on the other side of the third direction z. The third lower portion 552 is inclined relative to the bottom surface 52. The third intermediate portion 553 is located between the third upper portion 551 and the third lower portion 552 in the third direction z. The in-plane direction of the third intermediate portion 553 includes the third direction z. Viewed in the third direction z, the third intermediate portion 553 is positioned outwardly relative to the top surface 51 and the bottom surface 52.

As shown in FIGS. 5 to 7, the fourth side surface 56 connects to the top surface 51 and the bottom surface 52 and faces away from the third side surface 55 in the second direction y. The fourth side surface 56 includes a fourth upper portion 561, a fourth lower portion 562, and a fourth intermediate portion 563. The fourth upper portion 561 connects to the top surface 51 on one side in the third direction z, and the other side in the third direction z connects to the fourth upper portion 561. The fourth upper portion 561 is inclined relative to the top surface 51. The fourth lower portion 562 connects to the bottom surface 52 on one side in the third direction z and connects to the fourth intermediate portion 563 on the other side in the third direction z. The fourth lower portion 562 is inclined relative to the bottom surface 52. The fourth intermediate portion 563 is located between the fourth upper portion 561 and the fourth lower portion 562 in the third direction z. The in-plane direction of the fourth intermediate portion 563 includes the third direction z. Viewed in the third direction z, the third intermediate portion 553 is positioned outwardly relative to the top surface 51 and the bottom surface 52.

The first die pad 21, the second die pad 22, the first lead 23, the second lead 24, the third lead 25, the fourth lead 26, the plurality of first intermediate leads 31, and the plurality of second intermediate leads 32 all contain copper (Cu). The first die pad 21, the second die pad 22, and these leads are obtained from the same lead frame.

The first die pad 21 and the second die pad 22 are spaced apart from each other in the first direction x, as shown in FIGS. 1 and 2. In the semiconductor device A10, the first semiconductor element 11 and the insulating element 13 are mounted on the first die pad 21, and the second semiconductor element 12 is mounted on the second die pad 22. In this case, viewed in the third direction z, the area of the first die pad 21 is larger than the area of the second die pad 22. Alternatively, the first semiconductor element 11 may be mounted on the first die pad 21, while the second semiconductor element 12 and the insulating element 13 are mounted on the second die pad 22.

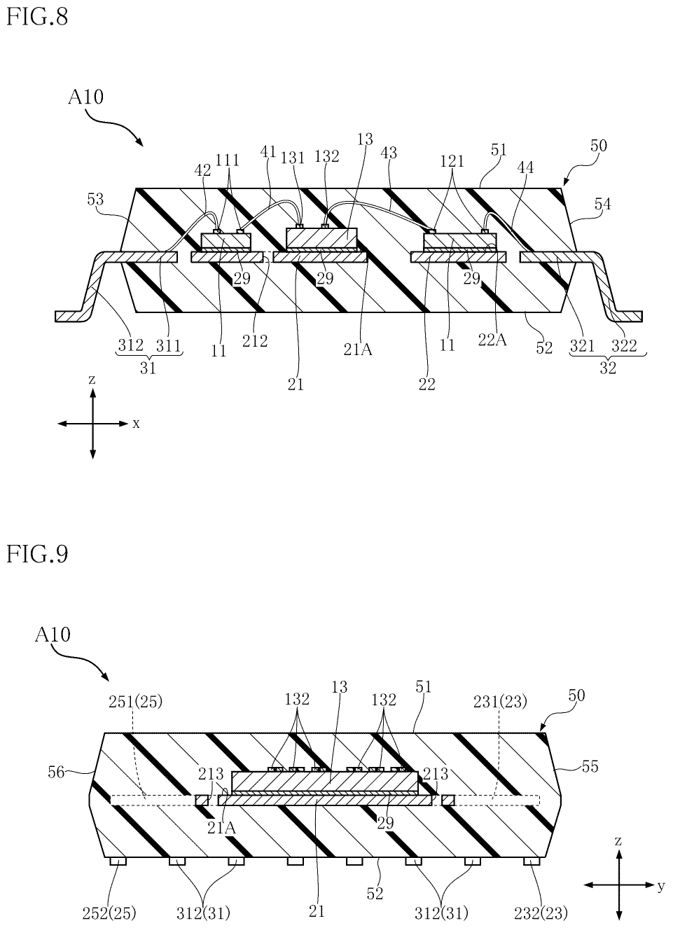

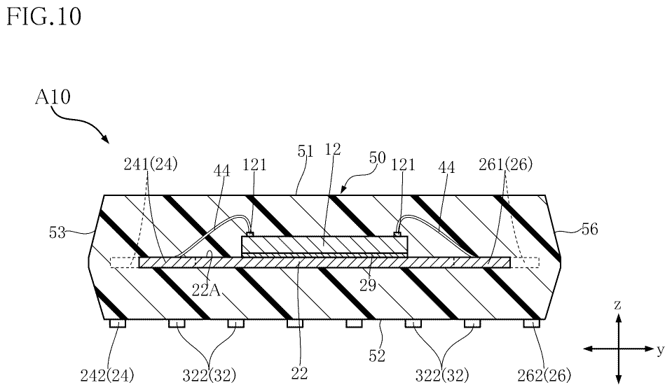

As shown in FIGS. 8 and 9, the first die pad 21 has a first mounting surface 21A facing one side in the third direction z. The first semiconductor element 11 and the insulating element 13 are each bonded to the first mounting surface 21A via the bonding layer 29. The bonding layer 29 is composed of a paste containing metal particles. The metal particles are, for example, silver (Ag). Therefore, the bonding layer 29 is conductive. Alternatively, the bonding layer 29 may be solder. The first die pad 21 is covered by the sealing resin 50.

As shown in FIGS. 2, 8, and 9, two first holes 211, a plurality of second holes 212, and two third holes 213 are provided on the first die pad 21. Each of the two first holes 211, the plurality of second holes 212, and the two third holes 213 penetrates the first die pad 21 in the third direction z. The two first holes 211 are positioned on both sides of the first semiconductor element 11 in the second direction y. Each of the two first holes 211 extends in the first direction x. The plurality of second holes 212 are located between the first semiconductor element 11 and the insulating element 13 in the first direction x. Each of the plurality of second holes 212 extends in the second direction y. The plurality of second holes 212 are arranged along the second direction y. Two third holes 213 are positioned on both sides of the insulating element 13 in the second direction y. Each of the two third holes 213 extends in the first direction x.

The first lead 23 includes a portion extending toward the first die pad 21, as shown in FIGS. 1 and 2, and is positioned closest from the third side surface 55 of the sealing resin 50. The first lead 23 is connected to one side of the first die pad 21 in the second direction y. The first lead 23 is spaced apart from the third side surface 55 and the fourth side surface 56 of the sealing resin 50. The first lead 23 is exposed externally from the first side surface 53 of the sealing resin 50. The first lead 23 has a first inner portion 231 and a first outer portion 232. The first inner portion 231 is connected to the first die pad 21 and is covered by the sealing resin 50. The first outer portion 232 is connected to the first inner portion 231 and is exposed externally. Viewed in the third direction z, the first outer portion 232 extends in the first direction x. As shown in FIG. 4, the first outer portion 232 is bent in a gull-wing shape when viewed in the second direction y. The surface of the first outer portion 232 is plated, for example, with tin.

The third lead 25, as shown in FIGS. 1 and 2, includes a portion extending toward the first die pad 21 and is positioned closest from the fourth side surface 56 of the sealing resin 50. The third lead 25 is connected to the side of the first die pad 21 opposite the side where the first lead 23 is located in the second direction y. The third lead 25 is spaced apart from the third side surface 55 and the fourth side surface 56 of the sealing resin 50. The third lead 25 is exposed externally from the first side surface 53 of the sealing resin 50. The third lead 25 has a third inner portion 251 and a third outer portion 252. The third inner portion 251 is connected to the first die pad 21 and is covered by the sealing resin 50. The third outer portion 252 is connected to the third inner portion 251 and is exposed externally. Viewed in the third direction z, the third outer portion 252 extends in the first direction x. As shown in FIG. 5, the third outer portion 252 is bent in a gull-wing shape when viewed in the second direction y. The surface of the third outer portion 252 is plated, for example, with tin.

As shown in FIG. 9, viewed in the second direction y, the first inner portion 231 of the first lead 23 and the third inner portion 251 of the third lead 25 each overlap the first die pad 21.

As shown in FIGS. 8 and 10, the second die pad 22 has a second mounting surface 22A facing the same side as the first mounting surface 21A of the first die pad 21 in the third direction z. The second semiconductor element 12 is bonded to the second mounting surface 22A via the bonding layer 29. The second die pad 22 is covered by the sealing resin 50.

The second lead 24 includes, as shown in FIGS. 1 and 2, a portion extending toward the second die pad 22 and is positioned closest from the third side surface 55 of the sealing resin 50. The second lead 24 is connected to one side of the second die pad 22 in the second direction y. The second lead 24 is spaced apart from the third side surface 55 and the fourth side surface 56 of the sealing resin 50. The second lead 24 is exposed externally from the second side surface 54 of the sealing resin 50. The second lead 24 has a second inner portion 241 and a second outer portion 242. The second inner portion 241 is connected to the second die pad 22 and is covered by the sealing resin 50. The second outer portion 242 is connected to the second inner portion 241 and is exposed externally. Viewed in the third direction z, the second outer portion 242 extends in the first direction x. As shown in FIG. 4, the second outer portion 242 is bent in a gull-wing shape when viewed in the second direction y. The surface of the second outer portion 242 is plated, for example, with tin.

The fourth lead 26 includes, as shown in FIGS. 1 and 2, a portion extending toward the second die pad 22 and is positioned closest from the fourth side surface 56 of the sealing resin 50. The fourth lead 26 connects to the side of the second die pad 22 opposite the side where the second lead 24 is positioned in the second direction y. The fourth lead 26 is spaced apart from the third side surface 55 and the fourth side surface 56 of the sealing resin 50. The fourth lead 26 is exposed externally from the second side surface 54 of the sealing resin 50. The fourth lead 26 has a fourth inner portion 261 and a fourth outer portion 262. The fourth inner portion 261 is connected to the second die pad 22 and is covered by the sealing resin 50. The fourth outer portion 262 is connected to the fourth inner portion 261 and is exposed externally. Viewed in the third direction z, the fourth outer portion 262 extends in the first direction x. As shown in FIG. 5, the fourth outer portion 262 is bent in a gull-wing shape when viewed in the second direction y. The surface of the fourth outer portion 262 is plated, for example, with tin.

As shown in FIG. 10, viewed in the second direction y, the second inner portion 241 of the second lead 24 and the fourth inner portion 261 of the fourth lead 26 each overlap the second die pad 22.

As shown in FIG. 3, viewed in the third direction z, each of the first lead 23 and the third lead 25 is spaced apart in the first direction x from the first virtual line VL1 toward the side where the first side surface 53 of the sealing resin 50 is located. The first virtual line VL1 passes through the center C1 of the first die pad 21, viewed in the third direction z, and extends along the second direction y.

As shown in FIG. 3, viewed in the third direction z, the second lead 24 and the fourth lead 26 each overlap the second virtual line VL2. The second virtual line VL2 passes through the center C2 of the second die pad 22, viewed in the third direction z, and extends along the second direction y.

As shown in FIG. 3, viewed in the third direction z, the first inner portion 231 of the first lead 23, the third inner portion 251 of the third lead 25, and each of the plurality of second holes 212 of the first die pad 21 overlap a third virtual line VL3 extending along the second direction y.

As shown in FIG. 3, the dimension L2 of the second inner portion 241 of the second lead 24 in the first direction x is equal to the dimension L1 of the first inner portion 231 of the first lead 23 in the first direction x. Viewed in the third direction z, the minimum distance d2 in the second direction y between the second inner portion 241 and the third side surface 55 of the sealing resin 50 is equal to the minimum distance d1 in the second direction y between the first inner portion 231 and the third side surface 55.

As shown in FIG. 3, the dimension L4 of the fourth inner portion 261 of the fourth lead 26 in the first direction x is equal to the dimension L3 of the third inner portion 251 of the third lead 25 in the first direction x. Viewed in the third direction z, the minimum distance d4 in the second direction y between the fourth inner portion 261 and the fourth side surface 56 of the sealing resin 50 is equal to the minimum distance d3 in the second direction y between the third inner portion 251 and the fourth side surface 56.

As shown in FIG. 4, a first gate mark 55A is formed on the third side surface 55 of the sealing resin 50. The first gate mark 55A includes a portion of the third lower portion 552 of the third side surface 55 and a portion of the third intermediate portion 553 of the third side surface 55. The surface roughness of the first gate mark 55A is greater than the surface roughness of the other areas of the third side surface 55 excluding the first gate mark 55A. As shown in FIG. 5, a second gate mark 56A is formed on the fourth side surface 56 of the sealing resin 50. The second gate mark 56A includes a portion of the fourth lower portion 562 of the fourth side surface 56 and a portion of the fourth intermediate portion 563 of the fourth side surface 56. The surface roughness of the second gate mark 56A is greater than the surface roughness of the other areas of the fourth side surface 56 excluding the second gate mark 56A.

Each of the first gate mark 55A and the second gate mark 56A is formed when the sealing resin 50 is separated from the resin filled into the runner of the molding die during the formation of the sealing resin 50 by the transfer mold forming process. The first gate mark 55A is formed at the resin inlet of the cavity of the molding die. The second gate mark 56A is formed at the resin outlet of the cavity of the molding die.

As shown in FIG. 3, the first gate mark 55A is located between the first inner portion 231 of the first lead 23 and the second inner portion 241 of the second lead 24. The second gate mark 56A is located between the third inner portion 251 of the third lead 25 and the fourth inner portion 261 of the fourth lead 26.

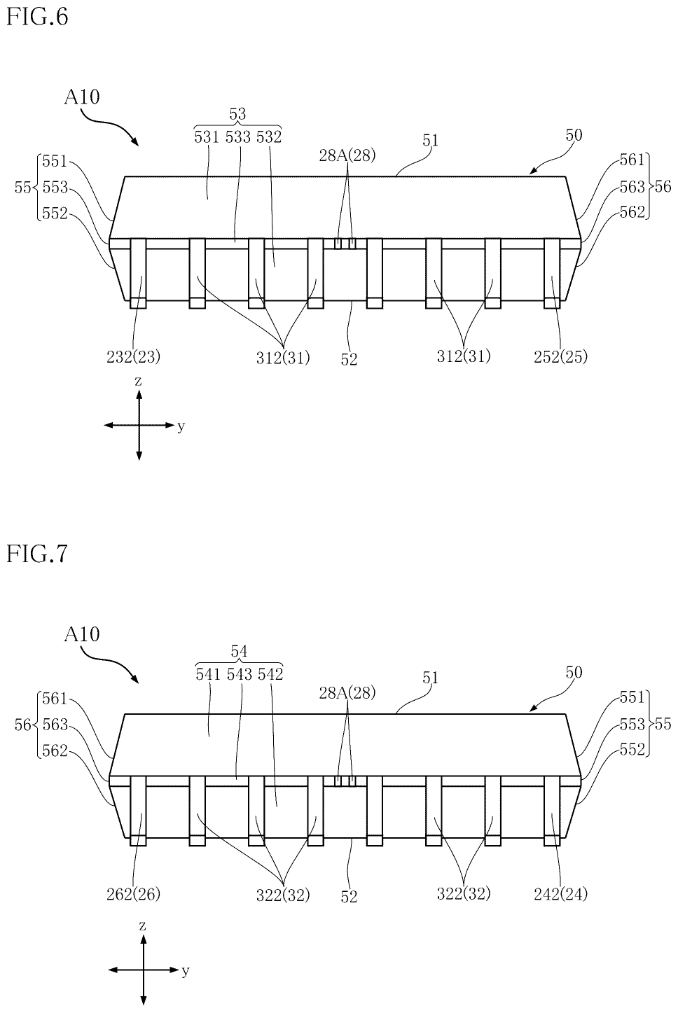

The two support leads 28 are spaced apart from each other in the first direction x, as shown in FIGS. 1 and 2. Each of the two support leads 28 extends in the first direction x. The two support leads 28 are individually connected to the first die pad 21 and the second die pad 22. As shown in FIGS. 6 and 7, each of the two support leads 28 has an end face 28A facing the first direction x. The end face 28A of the support lead 28, from among the two support leads 28, connected to the first die pad 21 is exposed from the first side surface 53 of the sealing resin 50. The end face 28A of the support lead 28, from among the two support leads 28, connected to the second die pad 22 is exposed from the second side surface 54 of the sealing resin 50.

The plurality of first intermediate leads 31 are located between the first lead 23 and the third lead 25 in the second direction y, as shown in FIGS. 1 and 2. The plurality of first intermediate leads 31 are positioned on the opposite side from the second die pad 22 relative to the first die pad 21 in the first direction x. The plurality of first intermediate leads 31 are arranged along the second direction y. At least one of the plurality of first intermediate leads 31 is conducted to the first semiconductor element 11 via one of the plurality of second wires 42.

As shown in FIGS. 2 and 8, each of the plurality of first intermediate leads 31 has an inner portion 311 and an outer portion 312. The inner portion 311 is covered by the sealing resin 50. The outer portion 312 connects to the inner portion 311 and is exposed externally from the first side surface 53 of the sealing resin 50. Viewed in the third direction z, the outer portion 312 extends in the first direction x. Viewed in the second direction y, the outer portion 312 is bent in a gull-wing shape. The shape of the outer portion 312 is identical to the shape of the first outer portion 232 of the first lead 23 shown in FIG. 4. The surface of the outer portion 312 is plated, for example, with tin.

The plurality of second intermediate leads 32 are located between the second lead 24 and the fourth lead 26 in the second direction y, as shown in FIGS. 1 and 2. The plurality of second intermediate leads 32 are positioned on the opposite side from the first die pad 21 relative to the second die pad 22 in the first direction x. The plurality of second intermediate leads 32 are arranged along the second direction y. At least one of the plurality of second intermediate leads 32 is conducted to the second semiconductor element 12 via one of the plurality of fourth wires 44.

As shown in FIGS. 2 and 8, each of the plurality of second intermediate leads 32 has an inner portion 321 and an outer portion 322. The inner portion 321 is covered by the sealing resin 50. The outer portion 322 connects to the inner portion 321 and is exposed externally from the second side surface 54 of the sealing resin 50. Viewed in the third direction z, the outer portion 322 extends in the first direction x. Viewed in the second direction y, the outer portion 322 is bent in a gull-wing shape. The shape of the outer portion 322 is identical to the shape of the second outer portion 242 of the second lead 24 shown in FIG. 4. The surface of the outer portion 322 is plated, for example, with tin.

Each of the plurality of first wires 41 is conductively bonded, as shown in FIGS. 2 and 8, to one of the plurality of third electrodes 131 of the insulating element 13 and to one of the plurality of first electrodes 111 of the first semiconductor element 11. This enables the first semiconductor element 11 to be conducted to the insulating element 13. The plurality of first wires 41 are arranged along the second direction y. Each of the plurality of first wires 41 spans one of the plurality of second holes 212 provided in the first die pad 21. The plurality of first wires 41 contain, for example, gold.

Each of the plurality of second wires 42 is conductively bonded to one of the plurality of first electrodes 111 of the first semiconductor element 11 and to the inner portion 311 of one of the plurality of first intermediate leads 31, as shown in FIGS. 2 and 8. Consequently, at least one of the plurality of first intermediate leads 31 is conducted to the first semiconductor element 11. At least one of the plurality of second wires 42 is conductively bonded to one of the plurality of first electrodes 111 and to the first inner portion 231 of the first lead 23. Consequently, the first lead 23 is conducted to the first semiconductor element 11. Furthermore, at least one of the plurality of second wires 42 is conductively bonded to one of the plurality of first electrodes 111 and to the third inner portion 251 of the third lead 25. Consequently, the third lead 25 is conducted to the first semiconductor element 11. At least one of the first lead 23 and the third lead 25 forms the ground of the first semiconductor element 11. The plurality of second wires 42 may contain, for example, gold. Additionally, each of the plurality of second wires 42 may comprise a core material containing copper and a coating material containing palladium that covers said core material.

Each of the plurality of third wires 43 is conductively bonded to one of the plurality of fourth electrodes 132 of the insulating element 13 and one of the plurality of second electrodes 121 of the second semiconductor element 12, as shown in FIGS. 2 and 8. Consequently, the second semiconductor element 12 is conducted to the insulating element 13. The plurality of third wires 43 are arranged along the second direction y. The plurality of third wires 43 span between the first die pad 21 and the second die pad 22. The plurality of third wires 43 include, for example, gold.

Each of the plurality of fourth wires 44 is conductively bonded to one of the plurality of second electrodes 121 of the second semiconductor element 12 and to the inner portion 321 of one of the plurality of second intermediate leads 32, as shown in FIGS. 2 and 8. Consequently, at least one of the plurality of second intermediate leads 32 is conducted to the second semiconductor element 12. At least one of the plurality of fourth wires 44 is conductively bonded to one of the plurality of second electrodes 121 and to the second inner portion 241 of the second lead 24. Consequently, the second lead 24 is conducted to the second semiconductor element 12. At least one of the plurality of fourth wires 44 is conductively bonded to one of the plurality of second electrodes 121 and to the fourth inner portion 261 of the fourth lead 26. Consequently, the fourth lead 26 is conducted to the second semiconductor element 12. At least one of the second lead 24 and the fourth lead 26 forms the ground of the second semiconductor element 12. The plurality of fourth wires 44 may, for example, contain gold. Additionally, each of the plurality of fourth wires 44 may include a core material containing copper and a coating material containing palladium that covers said core material.

In a motor driver circuit within an inverter device, a half-bridge circuit including a low-side (low potential side) switching element and a high-side (high potential side) switching element is typically configured. The following description pertains to cases where these switching elements are MOSFETs. Here, for the low-side switching element, both the source of the switching element and the reference electric potential of the gate driver driving the switching element are connected to ground. On the other hand, for the high-side switching element, both the source of the switching element and the reference electric potential of the gate driver driving the switching element correspond to the electric potential at the output node of the half-bridge circuit. Because the electric potential at the output node changes in response to the driving of the high-side switching element and the low-side switching element, the reference electric potential of the gate driver driving the high-side switching element also changes. When the high-side switching element is on, this reference electric potential becomes equivalent to the voltage applied to the drain of the high-side switching element (e.g., 600 V or higher). In the semiconductor device A10, the ground of the first semiconductor element 11 and the ground of the second semiconductor element 12 are configured to be separated. Therefore, when the semiconductor device A10 is used as a gate driver to drive the high-side switching element, a voltage equivalent to the voltage applied to the drain of the high-side switching element is transiently applied to the ground of second semiconductor element 12.

Next, the operational effect of the semiconductor device A10 is described.

The semiconductor device A10 includes the first die pad 21, the first semiconductor element 11, the second die pad 22, the second semiconductor element 12, the sealing resin 50, the first lead 23, the second lead 24, the third lead 25, and the fourth lead 26. The first lead 23, the second lead 24, the third lead 25, and the fourth lead 26 are each spaced apart from the third side surface 55 and the fourth side surface 56 of the sealing resin 50 and are exposed externally from either the first side surface 53 or second side surface 54 of the sealing resin 50. Viewed in the third direction z, the area of the first die pad 21 is larger than the area of the second die pad 22. Viewed in the third direction z, each of the first lead 23 and the third lead 25 is separated away in the first direction x from the first virtual line VL1 shown in FIG. 3 toward the side where the first side surface 53 of the sealing resin 50 is located. With the present configuration, the dimension of the second inner portion 241 of the second lead 24 covered by the sealing resin 50 in the first direction x can be set to a value closer to the dimension of the first inner portion 231 of the first lead 23 covered by the sealing resin 50 in the first direction x. Additionally, the dimension of the fourth inner portion 261 of the fourth lead 26 covered by the sealing resin 50 in the first direction x can be set to a value closer to the dimension of the third inner portion 251 of the third lead 25 covered by the sealing resin 50 in the first direction x. Here, during the formation of the sealing resin 50, the first lead 23, the second lead 24, the third lead 25, and the fourth lead 26 regulate the flow of the molten resin within the cavity of the molding die. Therefore, with the present configuration, the molten resin whose flow is regulated by the first lead 23, the second lead 24, the third lead 25, and the fourth lead 26 can easily spread throughout the entire first die pad 21 and second die pad 22. This results in a denser filling state of the sealing resin 50. Accordingly, the present configuration enables a more favorable filling state of the sealing resin 50 in the semiconductor device A10.

Viewed in the third direction z, the second lead 24 and the fourth lead 26 overlap the second virtual line VL2, which passes through the center C2 of the second die pad 22 and extends along the second direction y. With the present configuration, the dimension of the second inner portion 241 of the second lead 24 in the first direction x can be made substantially identical to the dimension of the first inner portion 231 of the first lead 23 in the first direction x. Concurrently, the dimension of the fourth inner portion 261 of the fourth lead 26 in the first direction x can be made substantially identical to the dimension of the third inner portion 251 of the third lead 25 in the first direction x. Consequently, the molten resin, whose flow is regulated by the first lead 23, the second lead 24, the third lead 25, and the fourth lead 26 within the cavity of the molding die, can be more easily distributed over the whole of the first die pad 21 and the second die pad 22.

Viewed in the second direction y, the first lead 23 and the third lead 25 each overlap the first die pad 21. Adopting the present configuration makes the flow rate of molten resin flowing on both sides of the third direction z, with respect to the first die pad 21, more uniform within the cavity of the molding die. Consequently, viewed in the third direction z, the filling state of the portion of the sealing resin 50 overlapping the entire first die pad 21 becomes denser.

Viewed in the second direction y, the second lead 24 and the fourth lead 26 each overlap the second die pad 22. Adopting the present configuration makes the flow rate of molten resin flowing on both sides of the third direction z, with respect to the second die pad 22, more uniform within the cavity of the molding die. Consequently, viewed in the third direction z, the filling state of the portion of the sealing resin 50 overlapping the entire second die pad 22 becomes denser.

The first gate mark 55A is formed on the third side surface 55 of the sealing resin 50. The first gate mark 55A is located between the first lead 23 and the second lead 24. With the present configuration, it can be prevented that the flow of molten resin entering the cavity from the runner of the molding is obstructed by the first lead 23 and the second lead 24.

The second gate mark 56A is formed on the fourth side surface 56 of the sealing resin 50. The second gate mark 56A is located between the third lead 25 and the fourth lead 26. With the present configuration, it can be prevented that the flow of molten resin flowing from the cavity of the molding die into the runner is obstructed by the third lead 25 and the fourth lead 26.

Viewed in the third direction z, the minimum distance d2 in the second direction y between the second inner portion 241 of the second lead 24 and the third side surface 55 of the sealing resin 50 is equal to the minimum distance d1 in the second direction y between the first inner portion 231 of the first lead 23 and the first side surface 53. This configuration allows the timing of the molten resin flowing into the cavity of the molding die to branch toward the first die pad 21 to be made identical (or substantially identical) to the timing of branching toward the second die pad 22. This results in more uniform distribution of the molten resin within the cavity.

The semiconductor device A10 further includes an insulating element 13 mounted on the first die pad 21. The first die pad 21 is provided with two first holes 211 and a second hole 212, each penetrating in the third direction z. The two first holes 211 are positioned on both sides of the first semiconductor element 11 in the second direction y. The second hole 212 is located between the first semiconductor element 11 and the insulating element 13 in the first direction x. This configuration allows molten resin to pass through the two first holes 211 and the second hole 212 within the cavity of the molding die, resulting in a denser filling state of the sealing resin 50.

The first lead 23 and the third lead 25 are each connected to the first die pad 21. Viewed in the third direction z, the first lead 23, the third lead 25, and the second hole 212 of the first die pad 21 each overlap a third virtual line VL3 extending along the second direction y. This configuration suppresses rotation of the first die pad 21 about the second direction y, which occurs when molten resin contacts the first die pad 21 within the cavity of the molding die.

Consequently, the coating thickness of the sealing resin 50 on the first die pad 21 can be made more uniform. In this case, as the second hole 212 has a shape to extend in the second direction y, the rotation of the first die pad 21 about the second direction y can be more effectively suppressed.

The semiconductor device A10 further includes a support lead 28. The support lead 28 is connected to the first die pad 21 and is exposed externally from the first side surface 53 of the sealing resin 50. With the present configuration, when a load in the third direction z acts on the first die pad 21, the support lead 28, together with the first lead 23 and the third lead 25, resists bending in the third direction z. This allows for greater stabilization of the posture of the first die pad 21.

### Second Embodiment

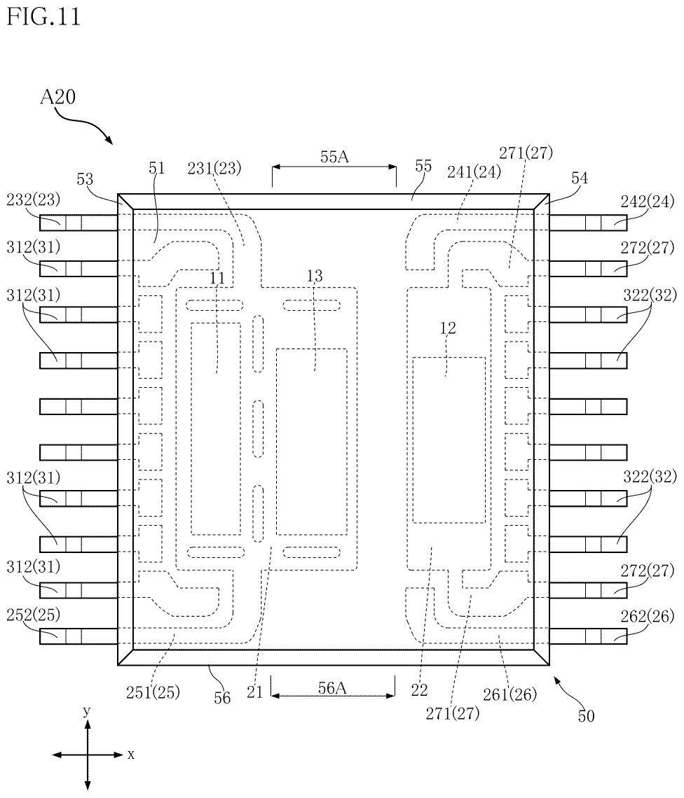

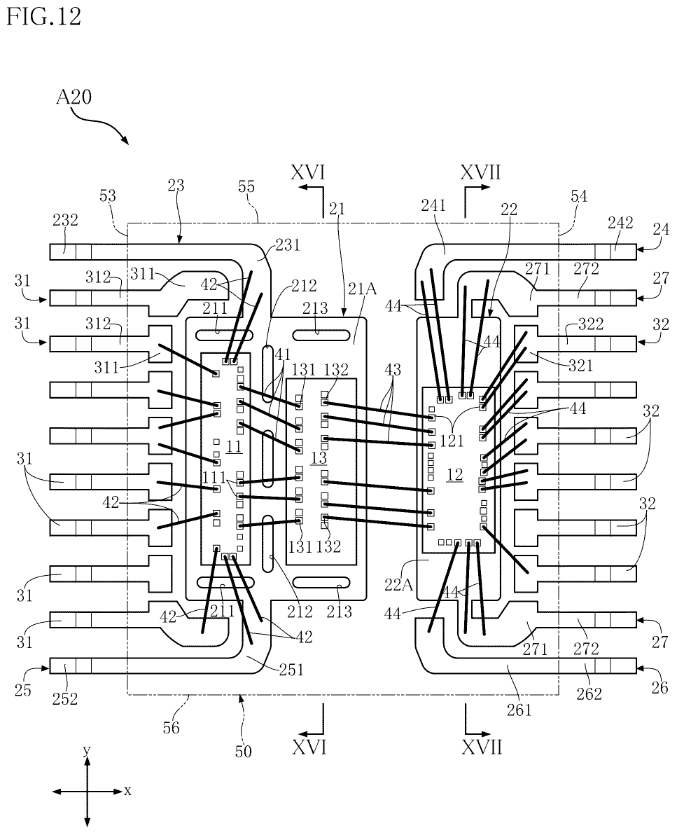

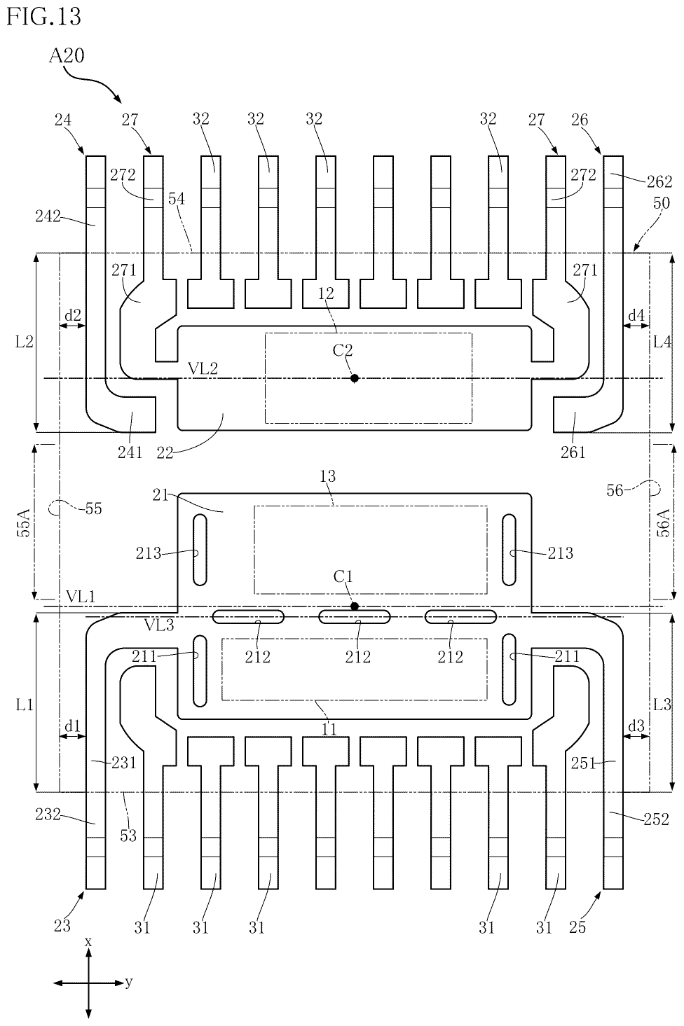

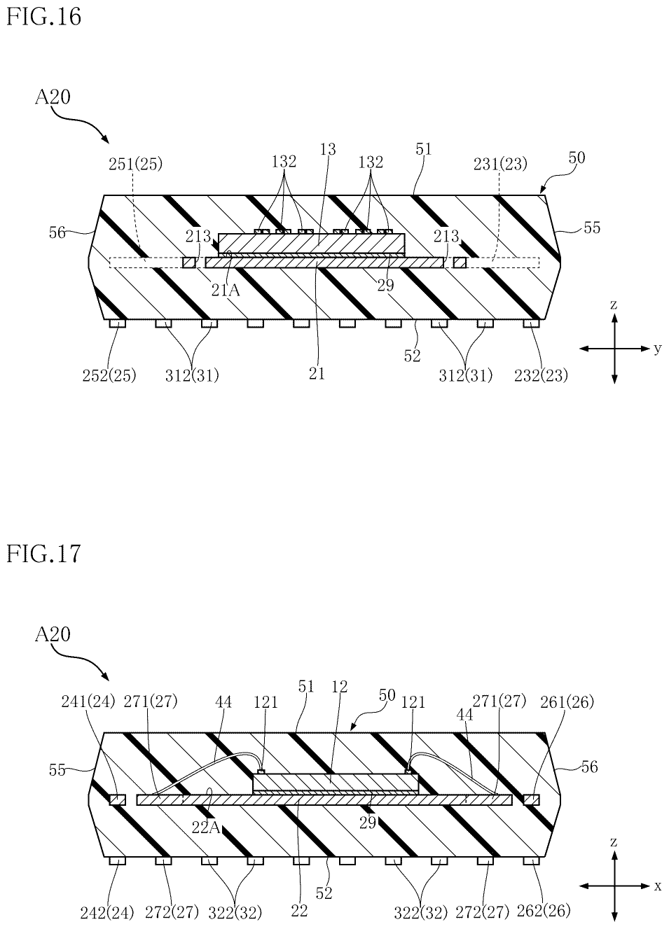

Based on FIGS. 11 to 17, a semiconductor device A20 according to a second embodiment of the present disclosure is described. In these figures, the elements identical or similar to those described as for the above semiconductor device A10 are designated by the same reference numerals, and the redundant descriptions are omitted. Here, FIG. 12 is showing the sealing resin 50 as being transparent, for ease of understanding. In FIG. 2, the outer contour of the sealing resin 50 is shown by an imaginary line. For ease of understanding, as differences from FIG. 12, FIG. 13 shows the first semiconductor element 11, the second semiconductor element 12, and the insulating element 13 as being transparent, and omits the depiction of each of the plurality of first wires 41 to the plurality of fourth wires 44. In FIG. 13, the outer contours of the first semiconductor element 11, the second semiconductor element 12, the insulating element 13, and the sealing resin 50 are each indicated by imaginary lines.

In the semiconductor device A20, the configuration of the second lead 24 and fourth lead 26, and the provision of two suspension leads 27 instead of two support leads 28, differ from the case of the semiconductor device A10.

As shown in FIGS. 11 and 12, the second lead 24 and fourth lead 26 are each spaced apart from the second die pad 22.

As shown in FIGS. 11 and 12, the two suspension leads 27 are individually connected to both sides in the second direction y of the second die pad 22. Each of the two suspension leads 27 is spaced apart from the third side surface 55 and the fourth side surface 56 of the sealing resin 50. Each of the two suspension leads 27 is exposed externally from the second side surface 54 of the sealing resin 50. The two suspension leads 27 are located between the second lead 24 and the fourth lead 26. Each of the two suspension leads 27 is conducted to one of the plurality of second electrodes 121 of the second semiconductor element 12 via one of the plurality of fourth wires 44.

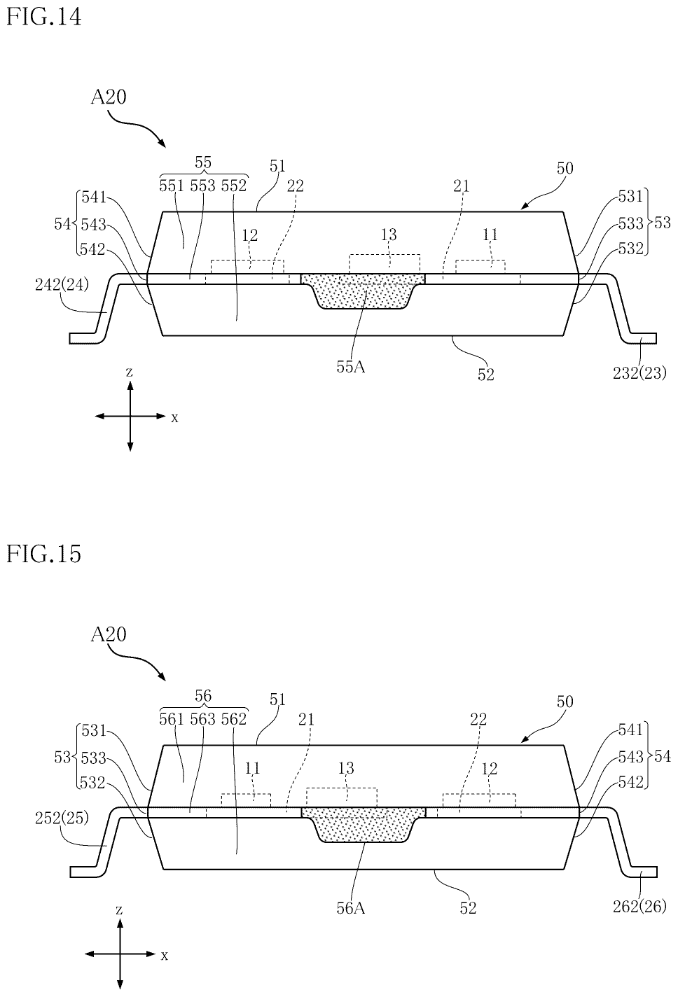

As shown in FIGS. 11 and 12, each of the two suspension leads 27 has an inner portion 271 and an outer portion 272. The inner portion 271 is connected to the second die pad 22 and is covered by the sealing resin 50. As shown in FIG. 13, the dimension of the inner portion 271 in the first direction x is smaller than the dimension of the second inner portion 241 of the second lead 24 and the dimension of the fourth inner portion 261 of the fourth lead 26, each in the first direction x. The outer portion 272 is connected to the inner portion 271 and is exposed externally. Viewed in the second direction y, the outer portion 272 is bent in a gull-wing shape. The shape of the outer portion 272 is identical to the shape of the second outer portion 242 shown in FIG. 14. The surface of the outer portion 272 is plated, for example, with tin.

As shown in FIG. 13, viewed in the second direction y, each of the second inner portion 241 of the second lead 24 and the fourth inner portion 261 of the fourth lead 26, and the inner portion 271 of each of the two suspension leads 27 overlap the second die pad 22.

As shown in FIG. 13, also in the semiconductor device A20, viewed in the third direction z, each of the first lead 23 and the third lead 25 is separated away in the first direction x from the first virtual line VL1 toward the side where the first side surface 53 of the sealing resin 50 is located. Additionally, viewed in the third direction z, the second lead 24 and the fourth lead 26 each overlap the second virtual line VL2.

As shown in FIG. 14, also in the semiconductor device A20, a first gate mark 55A is formed on the third side surface 55 of the sealing resin 50. Furthermore, as shown in FIG. 15, a second gate mark 56A is formed on the fourth side surface 56 of the sealing resin 50. As shown in FIG. 13, the first gate mark 55A is located between the first inner portion 231 of the first lead 23 and the second inner portion 241 of the second lead 24. The second gate mark 56A is located between the third inner portion 251 of the third lead 25 and the fourth inner portion 261 of the fourth lead 26.

Next, the operational effect of the semiconductor device A20 is described.

The semiconductor device A20 includes the first die pad 21, the first semiconductor element 11, the second die pad 22, the second semiconductor element 12, the sealing resin 50, the first lead 23, the second lead 24, the third lead 25, and the fourth lead 26. The first lead 23, the second lead 24, the third lead 25, and the fourth lead 26 are each spaced apart from the third side surface 55 and the fourth side surface 56 of the sealing resin 50 and are exposed externally from either the first side surface 53 or the second side surface 54 of the sealing resin 50. Viewed in the third direction z, the area of the first die pad 21 is larger than the area of the second die pad 22. Viewed in the third direction z, each of the first lead 23 and the third lead 25 is separated away in the first direction x from the first virtual line VL1 shown if FIG. 3 toward the side where the first side surface 53 of the sealing resin 50 is located. Therefore, the present configuration enables a more favorable filling state of the sealing resin 50 also in the semiconductor device A20. Furthermore, by having configurations common with those of the semiconductor device A10, the semiconductor device A20 can exhibit the operational effect equivalent to that of the semiconductor device A10.

### Third Embodiment

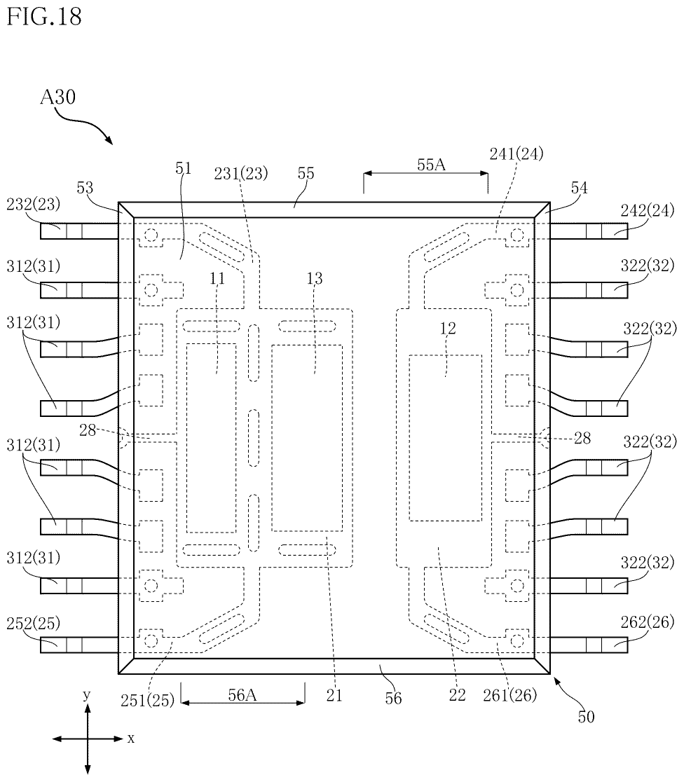

Based on FIGS. 18 to 20, the semiconductor device A30 according to a third embodiment of the present disclosure is described. In these figures, the elements identical or similar to those described as for the above semiconductor device A10 are designated by the same reference numerals, and the redundant descriptions are omitted.

In the semiconductor device A30, the configuration of sealing resin 50 differs from that of the semiconductor device A10.

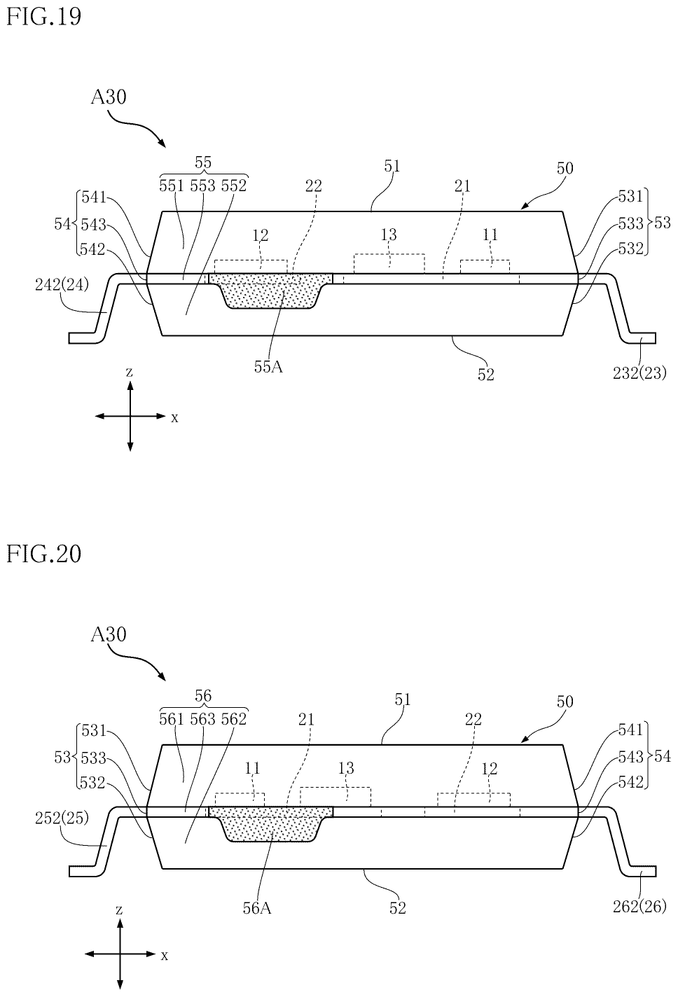

As shown in FIGS. 18 and 19, the first gate mark 55A formed on the third side surface 55 of sealing resin 50 is positioned closer to the second lead 24 than to the first lead 23. As shown in FIGS. 18 and 20, the second gate mark 56A formed on the fourth side surface 56 of the sealing resin 50 is positioned closer to the third lead 25 than to the fourth lead 26. Consequently, the first gate mark 55A and the second gate mark 56A are spaced apart from each other in the first direction x.

Next, the operational effect of the semiconductor device A30 is described.

The semiconductor device A30 includes the first die pad 21, the first semiconductor element 11, the second die pad 22, the second semiconductor element 12, the sealing resin 50, the first lead 23, the second lead 24, the third lead 25, and the fourth lead 26. The first lead 23, the second lead 24, the third lead 25, and the fourth lead 26 are each spaced apart from the third side surface 55 and the fourth side surface 56 of the sealing resin 50 and are exposed externally from either the first side surface 53 or the second side surface 54 of the sealing resin 50. Viewed in the third direction z, the area of the first die pad 21 is larger than the area of the second die pad 22. Also in the semiconductor device A30, viewed in the third direction z, each of the first lead 23 and the third lead 25 is separated away in the first direction x from the first virtual line VL1 shown in FIG. 3 toward the side where the first side surface 53 of the sealing resin 50 is located. Therefore, the present configuration enables a more favorable filling state of the sealing resin 50 also in the semiconductor device A30. Furthermore, by having configurations common with those of the semiconductor device A10, the semiconductor device A30 can exhibit the operational effect equivalent to that of the semiconductor device A10.

In the semiconductor device A30, the first gate mark 55A formed on the third side surface 55 of the sealing resin 50 is positioned closer to the second lead 24 than to the first lead 23. The second gate mark 56A formed on the fourth side surface 56 of the sealing resin 50 is positioned closer to the third lead 25 than to the fourth lead 26. The present configuration facilitates more uniform and balanced distribution of the molten resin throughout the cavity of the molding die when forming the sealing resin 50. Consequently, the filling state of the sealing resin 50 becomes even more favorable.

### Fourth Embodiment

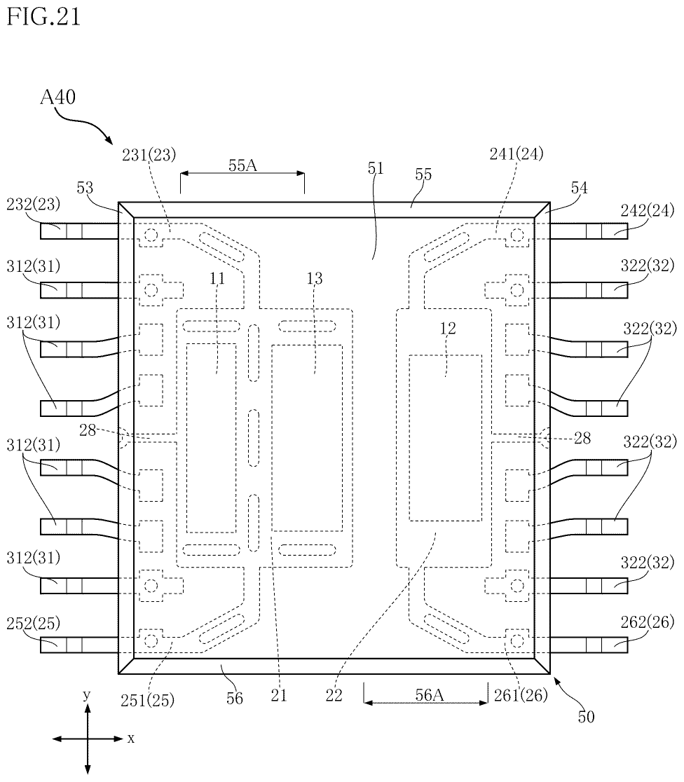

Based on FIGS. 21 to 23, a semiconductor device A40 according to a fourth embodiment of the present disclosure is described. In these figures, the elements identical or similar to those described as for the above semiconductor device A10 are designated by the same reference numerals, and the redundant descriptions are omitted.

In the semiconductor device A40, the configuration of sealing resin 50 differs from that of the semiconductor device A10.

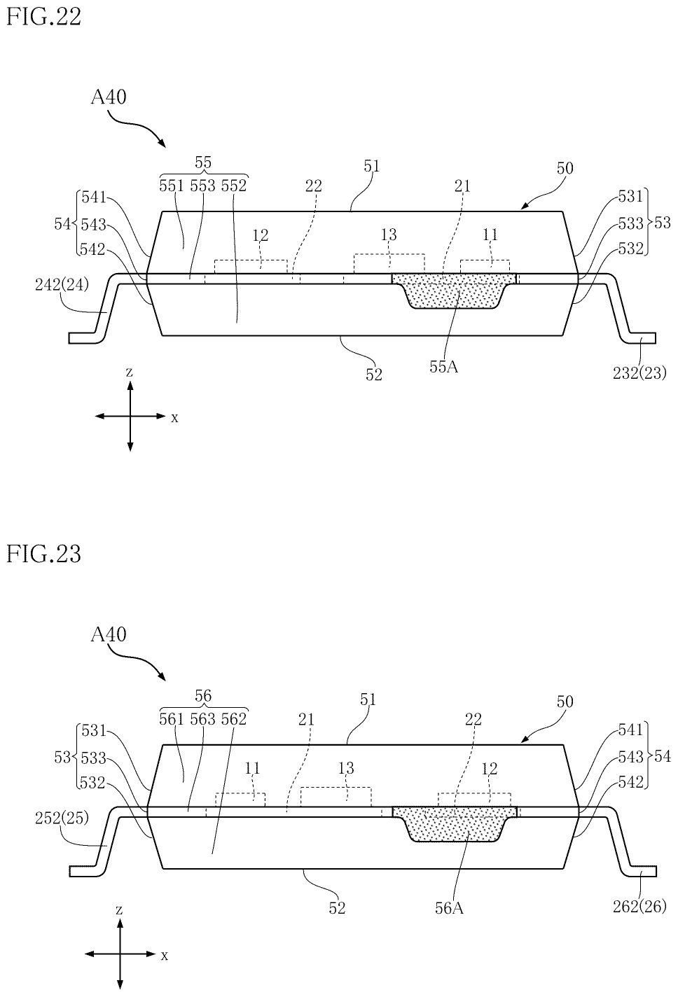

As shown in FIGS. 21 and 22, the first gate mark 55A formed on the third side surface 55 of sealing resin 50 is positioned closer to the first lead 23 than to the second lead 24. As shown in FIGS. 21 and 23, the second gate mark 56A formed on the fourth side surface 56 of the sealing resin 50 is positioned closer to the fourth lead 26 than to the third lead 25. Consequently, the first gate mark 55A and the second gate mark 56A are spaced apart from each other in the first direction x.

Next, the operational effect of the semiconductor device A40 is described.

The semiconductor device A40 includes the first die pad 21, the first semiconductor element 11, the second die pad 22, the second semiconductor element 12, the sealing resin 50, the first lead 23, the second lead 24, the third lead 25, and the fourth lead 26. The first lead 23, the second lead 24, the third lead 25, and the fourth lead 26 are each spaced apart from the third side surface 55 and the fourth side surface 56 of the sealing resin 50 and are exposed externally from either the first side surface 53 or second side surface 54 of the sealing resin 50. Viewed in the third direction z, the area of the first die pad 21 is larger than the area of the second die pad 22. Also in the semiconductor device A40, viewed in the third direction z, each of the first lead 23 and the third lead 25 is separated away in the first direction x from the first virtual line VL1 shown in FIG. 3 toward the side where the first side surface 53 of the sealing resin 50 is located. Therefore, according to the present configuration, the filling state of the sealing resin 50 can be more favorable also in the semiconductor device A40. Furthermore, by having configurations common with those of the semiconductor device A10, the semiconductor device A40 can exhibit the operational effect equivalent to that of the semiconductor device A10.

In the semiconductor device A40, the first gate mark 55A formed on the third side surface 55 of the sealing resin 50 is positioned closer to the first lead 23 than to the second lead 24. The second gate mark 56A formed on the fourth side surface 56 of the sealing resin 50 is positioned closer to the fourth lead 26 than to the third lead 25. The present configuration facilitates more uniform and balanced distribution of the molten resin throughout the cavity of the molding die when forming the sealing resin 50. Consequently, the filling state of the sealing resin 50 becomes even more favorable.

The present disclosure is not limited to the aforementioned embodiments. The specific configurations of the various parts of the present disclosure may be freely designed in various ways.

The present disclosure includes the embodiments described in the following clauses.

### Clause 1.

A semiconductor device comprising:
a first die pad;
a first semiconductor device mounted on the first die pad;
a second die pad spaced apart in a first direction from the first die pad;
a second semiconductor device mounted on the second die pad;
a sealing resin having a first side surface and a second side surface facing away from each other in the first direction, and a third side surface and a fourth side surface facing away from each other in a second direction perpendicular to the first direction, and covering the first die pad, the first semiconductor element, the second die pad, and the second semiconductor element;
a first lead including a portion extending toward the first die pad and being positioned closest from the third side surface;
a second lead including a portion extending toward the second die pad and being positioned closest from the third side surface;
a third lead including a portion extending toward the first die pad and being positioned closest from the fourth side surface;
a fourth lead including a portion extending toward the second die pad and being positioned closest from the fourth side surface,
wherein each of the first lead and the third lead is spaced apart from the third side surface and the fourth side surface, and is exposed externally from the first side surface,
each of the second lead and the fourth lead is spaced apart from the third side surface and the fourth side surface, and is exposed externally from the second side surface,
viewed in a third direction perpendicular to the first direction and the second direction, an area of the first die pad is larger than an area of the second die pad, and
viewed in the third direction, each of the first lead and the third lead is separated away in the first direction, from a first virtual line passing through a center of the first die pad and extending along the second direction, toward a side where the first side surface is located.

### Clause 2.

The semiconductor device according to clause 1, wherein viewed in the third direction, each of the second lead and the fourth lead passes through a center of the second die pad, and overlaps a second virtual line extending along the second direction.

### Clause 3.

The semiconductor device according to clause 2, wherein viewed in the second direction, each of the first lead and the third lead overlaps the first die pad.

### Clause 4.

The semiconductor device according to clause 3, wherein each of the first lead and the third lead is connected to the first die pad.

### Clause 5.

The semiconductor device according to clause 4, wherein viewed in the second direction, each of the second lead and the fourth lead overlaps the second die pad.

### Clause 6.

The semiconductor device according to clause 5, wherein each of the second lead and the third lead is connected to the second die pad.

### Clause 7.

The semiconductor device according to clause 5, further comprising two suspension leads individually connected to both sides in the second direction of the second die pad,
wherein each of the two suspension leads is spaced apart from the third side surface and the fourth side surface, and is exposed externally from the second side surface,
the two suspension leads are located between the second lead and the fourth lead, and
each of the second lead and the fourth lead is separated from the second die pad.

### Clause 8.

The semiconductor device according to clause 5,
wherein a first gate mark is formed on the third side surface,
a surface roughness of the first gate mark is greater than a surface roughness of other regions of the third side surface excluding the first gate mark,
a second gate mark is formed on the fourth side surface, and
a surface roughness of the second gate mark is greater than a surface roughness of other regions of the fourth side surface excluding the second gate mark.

### Clause 9.

The semiconductor device according to clause 8,
wherein the first gate mark is located between the first lead and the second lead, and
the second gate mark is located between the third lead and the fourth lead.

### Clause 10.

The semiconductor device according to clause 8,
wherein the first gate mark is located closer to the second lead than to the first lead, and
the second gate mark is located closer to the third lead than to the fourth lead.

### Clause 11.

The semiconductor device according to clause 8,
wherein the first gate mark is located closer to the first lead than to the second lead, and
the second gate mark is located closer to the fourth lead than to the third lead.

### Clause 12.

The semiconductor device according to clause 8,
wherein the first lead has a first inner portion covered by the sealing resin,
the second lead has a second inner portion covered by the sealing resin, and
a dimension of the second inner portion in the first direction is equal to a dimension of the first inner portion in the first direction.

### Clause 13.

The semiconductor device according to clause 12,
wherein the third lead has a third inner portion covered by the sealing resin,
the fourth lead has a fourth inner portion covered by the sealing resin, and
a dimension of the fourth inner portion in the first direction is equal to a dimension of the third inner portion in the first direction.

### Clause 14.

The semiconductor device according to clause 13, wherein viewed in the third direction, a minimum distance in the second direction between the second inner portion and the third side surface is equal to a minimum distance in the second direction between the first inner portion and the third side surface.

### Clause 15.

The semiconductor device according to any of clauses 5 to 14, further comprising an insulating element mounted on the first die pad,
wherein the insulating element is of and inductively coupled type, and
the insulating element is conducted to each of the first semiconductor element and the second semiconductor element.

### Clause 16.

The semiconductor device according to clause 15,
wherein the insulating element is positioned adjacent to the first semiconductor element in the first direction,
the first die pad has two first holes and a second hole, each penetrating the first die pad in the third direction,
the two first holes are positioned on both sides in the second direction of the first semiconductor device, and
the second hole is located between the first semiconductor element and the insulating element in the first direction.

### Clause 17.

The semiconductor device according to clause 16, wherein viewed in the third direction, the first lead, the third lead, and the second hole each overlap a third virtual line extending along the second direction.

### Clause 18.

The semiconductor device according to clause 17, further comprising a plurality of first intermediate leads located between the first lead and the third lead,
wherein at least one of the plurality of first intermediate leads is conducted to the first semiconductor element.

### Clause 19.

The semiconductor device according to clause 18, further comprising a plurality of second intermediate leads positioned between the second lead and the fourth lead,
wherein at least one of the plurality of second intermediate leads is conducted to the second semiconductor device.

REFERENCE NUMERALS

| | |
|---|---|
| A10, A20, A30, A40: Semiconductor | |
| device | |
| 11: First semiconductor element | 111: First electrode |
| 12: Second semiconductor element | 121: Second electrode |
| 13: Insulating element | 131: Third electrode |
| 132: Fourth electrode | 21: First die pad |
| 21A: First mounting surface | 211: First hole |
| 212: Second hole | 213: Third hole |
| 22: Second die pad | 22A: Second mounting surface |
| 23: First lead | 231: First inner portion |
| 32: First outer portion | 241: Second inner portion |
| 242: Second outer portion | 251: Third inner portion |
| 252: Third outer portion | |
| 261: Fourth inner portion | 262: Fourth outer portion |
| 27: Suspension lead | 271: Inner portion |
| 272: Outer portion | 28: Support lead |
| 28A: End face | 29: Bonding layer |
| 31: First Intermediate lead | 311: inner portion |
| 312: Outer portion | 32: Second Intermediate lead |
| 321: Inner portion | 322: Outer portion |
| 41: First wire | 42: Second wire |
| 43: Third wire | 44: Fourth wire |
| 50: Sealing resin | 51: Top surface |
| 52: Bottom surface | 53: First side surface |
| 531: First upper portion | 532: First lower portion |
| 533: First intermediate portion | 54: Second side surface |
| 541: Second upper portion | 542: Second lower portion |
| 543: Second intermediate portion | 55: Third side surface |
| 551: Third upper portion | 552: Third lower portion |
| 553: Third intermediate portion | 56: Fourth side surface |
| 561: Fourth upper portion | 562: Fourth lower portion |
| 563: Fourth intermediate portion | x: First direction |
| y: Second direction | z: Third direction |

1. A semiconductor device comprising:
a first die pad;
a first semiconductor device mounted on the first die pad;
a second die pad spaced apart in a first direction from the first die pad;
a second semiconductor device mounted on the second die pad;
a sealing resin having a first side surface and a second side surface facing away from each other in the first direction, and a third side surface and a fourth side surface facing away from each other in a second direction perpendicular to the first direction, and covering the first die pad, the first semiconductor element, the second die pad, and the second semiconductor element;
a first lead including a portion extending toward the first die pad and being positioned closest from the third side surface;
a second lead including a portion extending toward the second die pad and being positioned closest from the third side surface;
a third lead including a portion extending toward the first die pad and being positioned closest from the fourth side surface;
a fourth lead including a portion extending toward the second die pad and being positioned closest from the fourth side surface,
wherein each of the first lead and the third lead is spaced apart from the third side surface and the fourth side surface, and is exposed externally from the first side surface,
each of the second lead and the fourth lead is spaced apart from the third side surface and the fourth side surface, and is exposed externally from the second side surface,
viewed in a third direction perpendicular to the first direction and the second direction, an area of the first die pad is larger than an area of the second die pad, and
viewed in the third direction, each of the first lead and the third lead is separated away in the first direction, from a first virtual line passing through a center of the first die pad and extending along the second direction, toward a side where the first side surface is located.

2. The semiconductor device according to claim 1, wherein viewed in the third direction, each of the second lead and the fourth lead passes through a center of the second die pad, and overlaps a second virtual line extending along the second direction.

3. The semiconductor device according to claim 2, wherein viewed in the second direction, each of the first lead and the third lead overlaps the first die pad.

4. The semiconductor device according to claim 3, wherein each of the first lead and the third lead is connected to the first die pad.

5. The semiconductor device according to claim 4, wherein viewed in the second direction, each of the second lead and the fourth lead overlaps the second die pad.

6. The semiconductor device according to claim 5, wherein each of the second lead and the third lead is connected to the second die pad.

7. The semiconductor device according to claim 5, further comprising two suspension leads individually connected to both sides in the second direction of the second die pad,
wherein each of the two suspension leads is spaced apart from the third side surface and the fourth side surface, and is exposed externally from the second side surface,
the two suspension leads are located between the second lead and the fourth lead, and
each of the second lead and the fourth lead is separated from the second die pad.

8. The semiconductor device according to claim 5,
wherein a first gate mark is formed on the third side surface,
a surface roughness of the first gate mark is greater than a surface roughness of other regions of the third side surface excluding the first gate mark,
a second gate mark is formed on the fourth side surface, and
a surface roughness of the second gate mark is greater than a surface roughness of other regions of the fourth side surface excluding the second gate mark.

9. The semiconductor device according to claim 8,
wherein the first gate mark is located between the first lead and the second lead, and
the second gate mark is located between the third lead and the fourth lead.

10. The semiconductor device according to claim 8,
wherein the first gate mark is located closer to the second lead than to the first lead, and
the second gate mark is located closer to the third lead than to the fourth lead.

11. The semiconductor device according to claim 8,
wherein the first gate mark is located closer to the first lead than to the second lead, and
the second gate mark is located closer to the fourth lead than to the third lead.

12. The semiconductor device according to claim 8,
wherein the first lead has a first inner portion covered by the sealing resin,
the second lead has a second inner portion covered by the sealing resin, and
a dimension of the second inner portion in the first direction is equal to a dimension of the first inner portion in the first direction.

13. The semiconductor device according to claim 12,
wherein the third lead has a third inner portion covered by the sealing resin,
the fourth lead has a fourth inner portion covered by the sealing resin, and
a dimension of the fourth inner portion in the first direction is equal to a dimension of the third inner portion in the first direction.

14. The semiconductor device according to claim 13, wherein viewed in the third direction, a minimum distance in the second direction between the second inner portion and the third side surface is equal to a minimum distance in the second direction between the first inner portion and the third side surface.

15. The semiconductor device according to claim 5, further comprising an insulating element mounted on the first die pad,
wherein the insulating element is of and inductively coupled type, and
the insulating element is conducted to each of the first semiconductor element and the second semiconductor element.

16. The semiconductor device according to claim 15,
wherein the insulating element is positioned adjacent to the first semiconductor element in the first direction,
the first die pad has two first holes and a second hole, each penetrating the first die pad in the third direction,
the two first holes are positioned on both sides in the second direction of the first semiconductor device, and
the second hole is located between the first semiconductor element and the insulating element in the first direction.

17. The semiconductor device according to claim 16, wherein viewed in the third direction, the first lead, the third lead, and the second hole each overlap a third virtual line extending along the second direction.

18. The semiconductor device according to claim 17, further comprising a plurality of first intermediate leads located between the first lead and the third lead,
wherein at least one of the plurality of first intermediate leads is conducted to the first semiconductor element.

19. The semiconductor device according to claim 18, further comprising a plurality of second intermediate leads positioned between the second lead and the fourth lead,
wherein at least one of the plurality of second intermediate leads is conducted to the second semiconductor device.
